(19) United States
(12) Patent Application Publication
(10) Pub. No.: US 2011/0162709 A1
(43) Pub. Date: Jul. 7, 2011

(54) METHOD FOR THE TREATMENT OF SUBSTRATES, SUBSTRATE AND TREATMENT DEVICE FOR CARRYING OUT SAID METHOD

(75) Inventor: DIRK HABERMANN, Kirchzaarten (DE)

(73) Assignee: Gebr. Schmid GmbH & Co., Freudenstadt (DE)

(21) Appl. No.: 13/047,268

(22) Filed: Mar. 14, 2011

Related U.S. Application Data
(63) Continuation of application No. PCT/EP2009/006566, filed on Sep. 10, 2009.

(30) Foreign Application Priority Data
Sep. 15, 2008 (DE) DE 102008048540.3

(51) Int. Cl. H01L 31/0216; H01L 31/02

(52) U.S. Cl. 136/256; 438/73; 257/E31.11

(57) ABSTRACT

In a method for the treatment of substrates (13) for solar cells composed of silicon, after multiple etching the substrates are cleaned (18) with DI water. Afterwards, the substrates (13) are dried and heated in drying stations (22, 25). The heated substrates (13) are subsequently oxidized in an oxidation station (30) by means of oxidation gas (34) with a proportion of ozone.

### CROSS-REFERENCE TO RELATED APPLICATIONS

This application is a continuation of PCT Application No. PCT/EP2009/006566, filed Sep. 10, 2009, and claims priority to DE 10 2008 048 540.3 filed Sep. 15, 2008, the disclosures of which are hereby incorporated by reference in their entirety.

### FIELD OF APPLICATION AND PRIOR ART

The invention relates to a method for the treatment of substrates, in particular solar cell wafers, in accordance with the preamble of claim 1. The invention furthermore relates to substrates, in particular solar cell wafers, which have been treated by a method of this type, and to a treatment device for carrying out the method.

During the production of conventional solar cells with monocrystalline or polycrystalline p-Si wafers, by way of example, the surface is often textured by means of an etching process in order to improve its absorption properties. Said etching process is carried out using a mixture of sodium hydroxide solution or potassium hydroxide solution with isopropyl alcohol in the case of monocrystalline silicon, for example. Polycrystalline silicon is etched using a solution composed of hydrofluoric and nitric acid. Further etching-cleaning steps are subsequently carried out. One standard process for etching after the sawing of the substrates in order to eliminate sawing damage and for cleaning provides for firstly carrying out cleaning with DI water and then performing the texturing and sawing damage etching using solutions described above. Cleaning is then once again carried out with DI water, subsequently followed by a KOH etch or an NaOH etch in order to remove a thin layer of porous silicon and SiN complexes possibly present. Cleaning with Dl water is then once again carried out, followed by an HCl etch for neutralization and for removal of residual traces of metal. This is followed by an HF etch with renewed cleaning with DI water and then drying. The surface of the silicon wafer is then prepared for the subsequent diffusion process.

During said diffusion process, a pn junction is produced in the silicon by diffusion of phosphorus into a depth of approximately 0.5 μm. The pn junction then isolates the charge carriers formed by light during the operation of the solar cell. In order to produce said pn junction, the wafer is heated to approximately 800° C.-950° C. in a furnace, wherein a phosphorus source is present. In this case, phosphorus penetrates into the silicon surface, with the result that a layer doped with phosphorus is produced. In contrast to the positively conducting boron-doped base, said layer is negatively conducting. During this process, a phosphorus glass arises at the surface, and is removed in subsequent steps by means of etching using HF acid. Afterwards, a layer which has a thickness of around 80 nm and which is usually composed of SiN:H is applied for reducing the reflections and for passivation at the silicon surface. Finally, metallic contacts are applied by screen printing methods or the like on the front side and rear side. What is disadvantageous here, however, is that H₂O molecules are incorporated into the SiO₂ structure and a qualitatively non-optimum oxide is thus formed. Lifetime measurements of the charge carriers of surfaces passivated in this way exhibit considerably poorer values by comparison with oxides produced thermally, for example.

OBJECT AND HOW IT IS ACHIEVED

The invention is based on the object of providing a method mentioned in the introduction and also the use of said method and solar cell wafers treated by said method and a corresponding treatment device with which problems in the prior art can be avoided and, in particular, better qualities of the substrates, in particular in the case of solar cell wafers, can be provided.

This object is achieved by means of a method comprising the features of claim 1, a use comprising the features of claim 10, a solar cell wafer comprising the features of claim 11, and a treatment device comprising the features of claim 14. Advantageous and preferred configurations of the invention are the subject matter of the further claims and are explained in more detail below. Some of the features are explained only for one of the basic inventive concepts, but shall be applicable for all aspects of the invention. The wording of the claims is incorporated by express reference in the content of the description. Furthermore, the wording of the priority application DE 102008048540.3 of Sep. 15, 2008, is incorporated by express reference in the content of this description.

In the case of the method, the etching of the substrates is effected multiply with a plurality of cleaning steps in between, during which water or DI water is used. According to the invention, finally, the substrate is dried and heated in order as far as possible to remove water from the surface in order to dry the substrates. An oxidation of the substrate or of the surface thereof is subsequently effected by means of a gas mixture containing at least a small proportion of ozone. It is thereby possible, precisely in contrast to earlier wet oxidation, in the case of so-called dry oxidation, to avoid the incorporation of H₂O molecules into the silicon layer. In this case, the drying and heating can be effected by means of a heated gas mixture.

A gas mixture containing N₂, O₂ or O₃ as carrier gas, for example also a mixture of a plurality of these compounds, can advantageously be used for the oxidation or the so-called dry oxidation.

Although the drying and heating of the substrate can also be effected at room temperature, in principle, heating to higher temperatures is advantageously provided, for example to at least 50° C. Particularly advantageously, heating to at least 100° C. to 150° C. is effected.

In one configuration of the invention, a further cleaning step with DI water can additionally be effected before the step of drying and heating the substrate, that is to say for example after a last HF etch.

The method is advantageously carried out in an inline method, alternatively in a batch process. It is thus possible to achieve a high throughput with efficient implementation.

Although the method mentioned above can be used for many purposes, it is particularly advantageously used for processing substrates for solar cells or for solar cell wafers. It is precisely in this context that the abovementioned inline methods or batch methods are also suitable for processing large quantities.

A solar cell wafer treated by the method according to the invention can either comprise a layer of silicon that is treated in this way. Alternatively, it can be composed completely of silicon material.

The treatment device for substrates according to the invention has at least one etching device for the substrates and at least one cleaning device with water or DI water. Furthermore, at least one drying station with heating means is provided in order to as substantially as possible dry the surface of the substrates and remove water, wherein there is arranged downstream of the drying station an oxidation station for the substrate or the substrate surface, with introduction of a gas mixture containing at least a small proportion of ozone. The precise embodiment of the treatment device in specific detail with various devices and workstations can be inferred from the method steps described above and be adapted thereto.

These and further features emerge not only from the claims but also from the description and the drawing, wherein the individual features can be realized in each case by themselves or as a plurality in the form of subcombinations in an embodiment of the invention and in other fields and can constitute advantageous and inherently protectable embodiments for which protection is claimed here. The subdivision of the application into individual sections and subheadings does not restrict the validity of the statements made thereunder.

### DETAILED DESCRIPTION OF THE EXEMPLARY EMBODIMENT

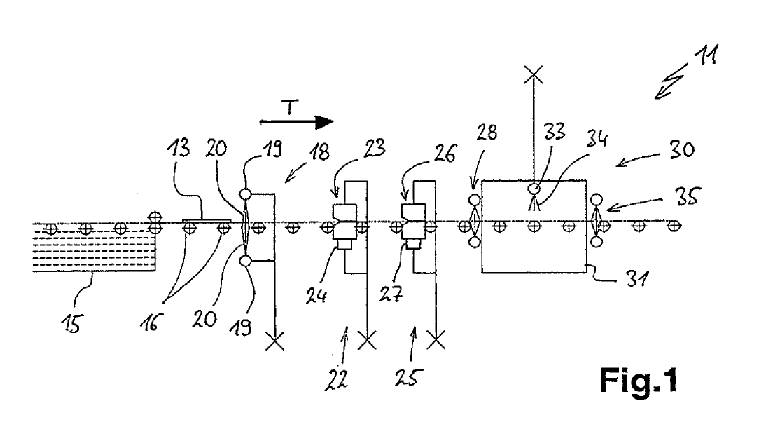

FIG. 1 schematically illustrates a treatment device 11, which is intended to be explained per se and on the basis of which the method according to the invention is also explained.

The treatment device 11 is provided for substrates, one substrate 13 of which is illustrated. It is moved in the transport direction T and comes from an etching device 15, which can be constructed in a conventional manner. The transport of the substrate 13 or of a series of successive substrates, which are not illustrated here for the sake of clarity, takes place on rollers 16, wherein the rollers 16 form a type of roller conveyor.

Downstream of the etching device 15, the substrate 13 passes through the rinsing station 18. By means of rinsing nozzles 19, DI water 20 is applied to the substrates 13 from the top and from the bottom in order to rinse or clean the surface of the substrate. Rinsing stations of this type can also be provided upstream of the etching device 15.

Downstream of the rinsing station 18, the substrate 13 passes through the first drying station 22 in transport direction T. Said drying station has a fan 23 and additionally also a heating means 24. By way of example, normal electrical heaters or else radiant heating elements and also conventional fans can be used for this purpose. By means of the fan action, firstly water situated on the surfaces of the substrate 13 is removed or driven away over the edges. Furthermore, part of the water evaporates as a result of the effect of the heating means 24. Furthermore, the heating can serve for advantageous preparation of the substrates for a subsequent oxidation.

Downstream of the first drying station 22 there follows a second drying station 25, which also has a fan 26 and a heating means 27. Two drying stations are provided here in order that the device 11 can be operated in continuous operation and it is ensured that the substrates 13 are also actually dried and, if appropriate, heated. They can also be identical.

Downstream of the second drying station 25, the substrates 13 pass through a lock 28 into an oxidation station 30. The latter has a chamber 31, in which a nozzle 33 is provided above the substrates 13 or the rollers 16 serving for transport. By means of the nozzle 33, an oxidation gas 34 is introduced into the chamber 31 for the oxidation of the substrates 13 or the surfaces thereof. By means of a lock 35, a substrate 13 is then discharged from the oxidation station 30.

As has been explained above, at the drying stations 22 and 25 the substrates 13 can be heated to at least 50° C., advantageously even higher, for example 100° C. to 150° C. This heating brings about not only better drying of the substrates, that is to say the removal of water, but also preparation for the oxidation, such that an optimized passivation and preparation of the surface for a phosphorus diffusion, for example, subsequently becomes possible. Furthermore, as a result of the heating at the drying stations, it is possible that the subsequent oxidation can take place in a device without a dedicated heater or heating means, in which case the oxidation also proceeds better as a result of the heating. A renewed incorporation of H₂O molecules into the silicon structure or the SiO₂ structure produced is also avoided as a result of the dry oxidation in the oxidation station 30. Specifically, this incorporation of H₂O molecules leads, in the case of lifetime measurements of the charge carriers, to poorer values by comparison with the substrates oxidized in dry and heated fashion according to the invention.

As has been described in the introduction, the oxidation gas 34 in the oxidation station 30 can be nitrogen, oxygen or ozone. In any event, however, an at least small minimum proportion of ozone should be contained since the latter is particularly well suited to the oxidation on account of its high reactivity, inter alia.

1. A method for treatment of substrates such as solar cells, wherein said substrates contain silicon or comprise silicon material at least on an outer side, wherein, during said treatment, a multiple etching of said substrates is effected and a plurality of cleaning steps with water or DI water in between are effected, wherein, finally, said substrates are dried and heated in order to as far as possible dry a surface of said substrates on said outer side and remove said water, wherein subsequently an oxidation of said substrates or of said surface is effected by means of a gas mixture containing at least a small proportion of ozone.

2. The method according to claim 1, wherein said substrates are dried and heated by means of a heated gas.

3. The method according to claim 1, wherein said gas mixture for said oxidation comprises constituents of the following group: N₂, O₂, O₃.

4. The method according to claim 1, wherein said oxidation is a dry oxidation of said substrates or of said surface.

5. The method according to claim 4, wherein said dry oxidation of said substrates or of said surface is being effected with a dry gas mixture.

6. The method according to claim 1, wherein said substrates are heated to a temperature of at least 50° C. during said drying and heating step.

7. The method according to claim 6, wherein said substrates are heated to a temperature of at least 100° C. to 150° C. during said drying and heating step.

8. The method according to claim 1, wherein said substrates are cleaned again with DI water directly before said drying and heating step.

9. The method according to claim 1, wherein it is carried out in an inline method.

10. Use of a method according to claim 1 for processing said substrates for solar cells or solar cell wafers.

11. A solar cell wafer, wherein it has been treated by a method according to claim 1.

12. The solar cell wafer according to claim 11, wherein it is coated with silicon.

13. The solar cell wafer according to claim 11, wherein it is composed of silicon.

14. A treatment device for substrates for solar cells, wherein said substrates contain silicon or comprise silicon material at least on their outer side, wherein said treatment device has at least one etching device for said substrates and at least one cleaning device with water or Dl water, wherein at least one drying station with heating means is provided in order to as far as possible dry a surface of said substrates and remove water, wherein there is arranged downstream of said drying station an oxidation station for said substrates or said substrate surface, with introduction of a gas mixture containing at least a small proportion of ozone.

15. The treatment device according to claim 14, wherein two of said drying stations, are provided.
